(19) United States
(12) Patent Application Publication
(10) Pub. No.: US 2010/0297790 A1
(43) Pub. Date: Nov. 25, 2010

(54) METHOD FOR PRODUCING SEMICONDUCTOR DEVICES

(75) Inventors: Seiji Nakahata, Hyogo (JP); Shinsuke Fujiwara, Hyogo (JP)

Correspondence Address: DRINKER BIDDLE & REATH (DC), 1500 K STREET, N.W., SUITE 1100, WASHINGTON, DC, 20005-1209, US

(73) Assignee: SUMITOMO ELECTRIC INDUSTRIES, LTD

(21) Appl. No.: 12/811,567

(22) PCT Filed: Dec. 12, 2008
(86) PCT No.: PCT/JP2008/072647

§ 371 Date: Jul. 2, 2010

(30) Foreign Application Priority Data
Jan. 7, 2008 (JP) 2008-000635

(51) Int. Cl. H01L 21/66

(52) U.S. Cl. 438/16; 257/E21.529

(57) ABSTRACT

The present invention provides a method for producing semiconductor devices by which the fraction defective upon division into chips is reduced and the yield is enhanced.

A method for producing semiconductor devices according to the present invention includes a dislocation-density evaluation step of measuring a dislocation density of sections of GaN substrates, the sections intersecting with principal surfaces of the GaN substrates, and selecting a GaN substrate in which the dislocation density is a predetermined value or less; and a division step of, after a functional device portion is epitaxially grown on the GaN substrate having been selected in the dislocation-density evaluation step, dividing the GaN substrate into chip-shaped parts.

### TECHNICAL FIELD

The present invention relates to a method for producing semiconductor devices.

### BACKGROUND ART

Single crystal GaN substrates have been used for the production of semiconductor devices such as light emitting diodes (LEDs) for the purpose of enhancing various device characteristics such as light-emission efficiency. Such a semiconductor device is generally produced from a GaN substrate by forming an epitaxial layer on the GaN substrate, forming electrodes on the back side of the substrate and on the epitaxial layer, and subsequently dividing the substrate into chip-shaped parts.

For example, Patent Document 1 discloses a method for affixing the wafer having semiconductor devices formed on the principal surface of the substrate to a reinforcing plate, subsequently dividing the wafer into chips by scribing, and removing the chips from the reinforcing plate.

In the formation of semiconductor devices from GaN substrates, for the purpose of reducing generation of defectives, various methods have been employed for reducing the defect density of GaN substrates, in particular, the density of threading dislocations in the principal surfaces of GaN substrates, that is, the density of threading dislocations perpendicular to the growth directions of GaN crystals. These methods are, for example, an epitaxial lateral overgrowth (ELO) method using a SiO₂ mask and growth of a GaN crystal on a base substrate that has been processed so as to have projections and recesses.

[Patent Document 1] Japanese Unexamined Patent Application Publication No. 2002-329684

### DISCLOSURE OF INVENTION

### Problems to be Solved by the Invention

However, when semiconductor devices are formed from a plurality of GaN substrates by the above-described methods under the same conditions, the fraction defective varies depending on each GaN substrate used and hence the yield varies, which is problematic. It has been confirmed that such defectives are mainly caused by chipping, burrs, and cracks upon division of GaN substrates into chip-shaped parts after formation of epitaxial layers, electrodes, and the like on the GaN substrates.

The present invention has been achieved under these circumstances. An object of the present invention is to provide a method for producing semiconductor devices by which the fraction defective upon division into chips is reduced and the yield is enhanced.

### Means for Solving the Problems

To achieve the object, a method for producing semiconductor devices according to the present invention includes a dislocation-density evaluation step of measuring a dislocation density of sections of GaN substrates, the sections intersecting with principal surfaces of the GaN substrates, and selecting a GaN substrate in which the dislocation density is a predetermined value or less; and a division step of, after a functional device portion is epitaxially grown on the GaN substrate having been selected in the dislocation-density evaluation step, dividing the GaN substrate into chip-shaped parts.

The inventors have found that generation of chipping, burrs, and cracks upon division of a GaN substrate into chip-shaped parts after formation of an epitaxial layer, electrodes, and the like on the GaN substrate is closely related to the defect density of the GaN substrate, in particular, the defect density in the lateral direction. Accordingly, by measuring a dislocation density of sections of GaN substrates intersecting with the principal surfaces of the GaN substrates, the dislocation density corresponding to the defect density in the lateral direction, and selecting and using a GaN substrate in which the dislocation density is a predetermined value or less, generation of defectives upon division of the substrate into chip-shaped parts is reduced. Thus, the yield of semiconductor devices is enhanced.

In the method for producing semiconductor devices according to the present invention, the sections are preferably along cleavage planes of the GaN substrates.

It has been confirmed that chipping, burrs, and cracks upon the division into chip-shaped parts are generated in a large number when the division into chip-shaped parts is conducted along cleavage planes. Accordingly, by measuring a dislocation density of surfaces along cleavage planes and performing the selection, the selection can be more appropriately performed. As a result, the yield of semiconductor devices is enhanced.

In the method for producing semiconductor devices according to the present invention, in the dislocation-density evaluation step, the dislocation density is preferably measured by a cathodoluminescence method or a light-scattering tomography method.

By measuring the dislocation density in a nondestructive manner by a cathodoluminescence method or a light-scattering tomography method, the production yield of semiconductor devices can be further enhanced compared with a destructive inspection.

In the method for producing semiconductor devices according to the present invention, the predetermined value is preferably 3.0×10⁶/cm².

When the dislocation density is the above-described value or less, the yield of semiconductor devices is considerably enhanced. Accordingly, the selection of GaN substrates is preferably conducted with the above-described value.

A principal surface of the GaN substrate preferably has a threading dislocation density of 4.2×10⁶/cm² or less.

### ADVANTAGES

The present invention provides a method for producing semiconductor devices by which the fraction defective upon division into chips is reduced and the yield is enhanced.

### BRIEF DESCRIPTION OF DRAWINGS

FIG. 1A is a sectional view of a semiconductor device 110 according to a first embodiment of the present invention.

FIG. 1B is a sectional view of the semiconductor device 110 according to the first embodiment of the present invention.

FIG. 2 is a schematic view illustrating a GaN substrate 1 used for producing the semiconductor devices 110 according to the first embodiment of the present invention.

FIG. 3 is a sectional view of a semiconductor device 120 according to a second embodiment of the present invention.

FIG. 4 is a sectional view of a semiconductor device 130 according to a third embodiment of the present invention.

FIG. 5 is a sectional view of a semiconductor device 140 according to a fourth embodiment of the present invention.

FIG. 6 is a sectional view of a semiconductor device 150 according to a fifth embodiment of the present invention.

FIG. 7 is a graph illustrating the relationship between lateral-direction dislocation density and chip yield.

FIG. 8 is a graph illustrating the relationship between principal-surface threading dislocation density and device yield.

### REFERENCE NUMERALS

1 GaN substrate
1A base
10 OF surface
30 functional device portion
110 semiconductor device (LD)
120 semiconductor device (LED)
130 semiconductor device (HEMT)
140 semiconductor device (Schottky diode)
150 semiconductor device (MIS-type transistor)

### BEST MODES FOR CARRYING OUT THE INVENTION

Hereinafter, embodiments of the present invention will be described in detail with reference to the attached drawings. In descriptions for the drawings, the same or equivalent elements are denoted with the same reference numerals and overlapped descriptions are omitted. The dimensional scales of the drawings do not necessarily match those in the descriptions.

### First Embodiment

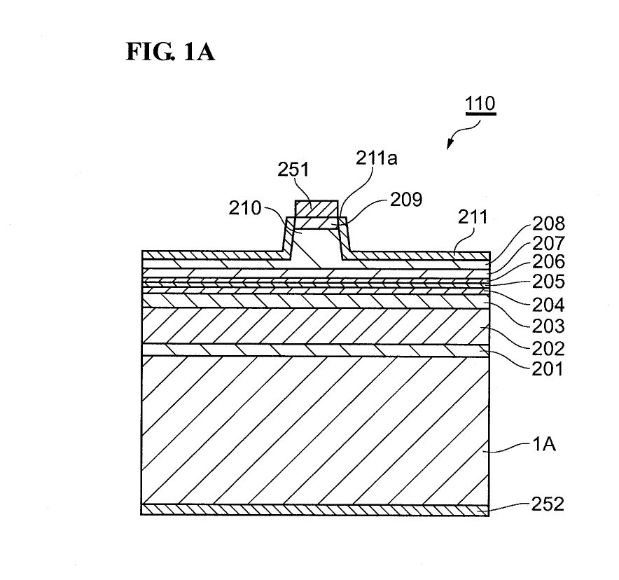

FIG. 1A is a sectional view of a semiconductor device 110 according to a first embodiment of the present invention. As illustrated in FIG. 1A, the semiconductor device 110 according to the first embodiment includes a base 1A constituted by a GaN substrate; a semiconductor layer in which an n-type GaN buffer layer 201, an n-type AlGaN cladding layer 202, an n-type GaN optical waveguide layer 203, an active layer 204, an undoped InGaN antidegradation layer 205, a p-type AlGaN cap layer 206, a p-type GaN optical waveguide layer 207, a p-type AlGaN cladding layer 208, and a p-type GaN contact layer 209 are sequentially formed on the principal surface of the base 1A; a p-side electrode 251 formed on the top of the p-type GaN contact layer 209; an n-side electrode 252 formed on the back surface of the base 1A; and a SiO₂ insulation film 211 covering the p-type AlGaN cladding layer 208. The semiconductor device 110 functions as a laser diode (LD).

The semiconductor devices 110 according to the first embodiment are produced by, for example, the following method. First, as illustrated in FIG. 1B, the n-type GaN buffer layer 201, the n-type AlGaN cladding layer 202, the n-type GaN optical waveguide layer 203, the active layer 204, the undoped AlGaN antidegradation layer 205, the p-type AlGaN cap layer 206, the p-type GaN optical waveguide layer 207, the p-type AlGaN cladding layer 208, and the p-type GaN contact layer 209 are sequentially formed on the principal surface of a GaN substrate 1 by a MOCVD method. Next, after a SiO₂ film is formed by a CVD method over the entire principal surface of the p-type GaN contact layer 209, the SiO₂ film is patterned by lithography. Next, as illustrated in FIG. 1A, the p-type AlGaN cladding layer 208 is etched to a predetermined depth in the thickness direction to thereby form a ridge 210. The SiO₂ film is then removed and the SiO₂ insulation film 211 is subsequently formed over the entire surface of the substrate. Next, an opening 211a is formed in the SiO₂ insulation film by formation of a resist pattern and etching. The p-side electrode 251 is formed by a liftoff process only on the principal surface of the p-type GaN contact layer 209. The n-side electrode 252 is subsequently formed on the back surface of the GaN substrate 1 and the GaN substrate 1 is then divided into chip-shaped parts to thereby provide LDs serving as the semiconductor devices 110. The SiO₂ films may also be formed by a vacuum deposition method, a sputtering method, or the like. The SiO₂ films may be etched by a reactive ion etching (RIE) method using an etching gas containing fluorine.

Herein, a method for producing the GaN substrate 1 used for producing the semiconductor devices 110 according to the first embodiment will be described.

First, a GaN single crystal is grown on a base substrate. The base substrate is preferably composed of sapphire, ZnO, SiC, AlN, GaAs, LiAlO, GaAlLiO, or GaN. A method for growing a GaN single crystal on a base substrate is not particularly restricted and a vapor phase growth method such as a metal organic chemical vapor deposition (MOCVD) method or a hydride vapor phase epitaxy method, or a liquid phase growth method such as a sodium flux method or an ammonothermal method can be used. A GaN single crystal grown by such a method is removed from the base substrate to thereby provide a GaN substrate constituted by the GaN single crystal.

In a method for producing the semiconductor devices 110 according to the first embodiment, before semiconductor layers (functional device portions) are formed on the principal surfaces of the GaN substrates 1, a dislocation-density evaluation step is performed in which the dislocation density of sections of the GaN substrates 1 is measured, the sections intersecting with the principal surfaces of the GaN substrates 1, and GaN substrates in which the dislocation density is a predetermined value or less are selected.

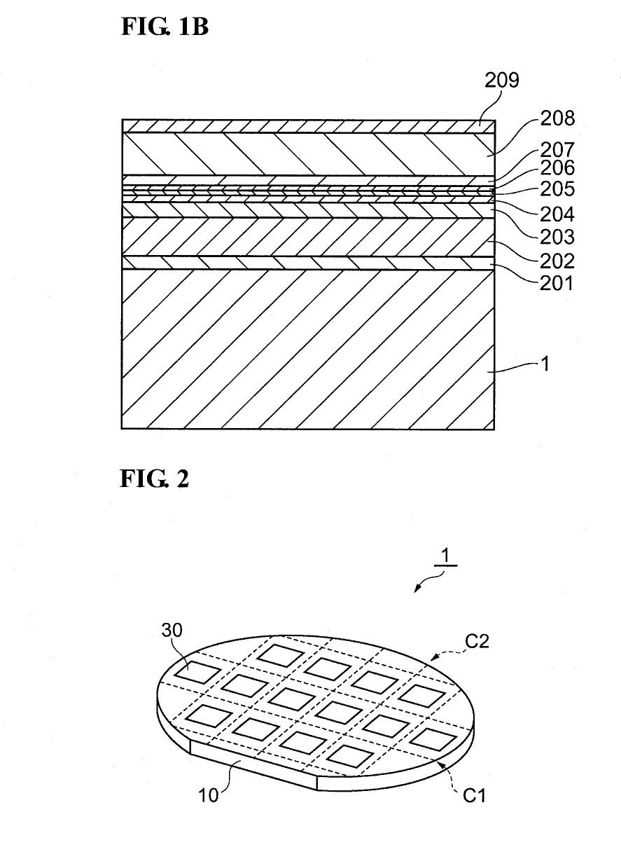

FIG. 2 is a schematic view illustrating the GaN substrate 1 used for producing semiconductor devices according to the first embodiment. FIG. 2 illustrates the state in which functional device portions 30 have been formed on the principal surface of the GaN substrate 1 in accordance with a method for producing the semiconductor devices 110 according to the first embodiment. In a method for producing the semiconductor devices 110 according to the first embodiment, semiconductor layers are formed as the functional device portions 30 on the principal surface of the GaN substrate 1 and the GaN substrate 1 is subsequently divided into chip-shaped parts along the dotted lines illustrated in FIG. 2. At this time, a division direction C1 is a direction along a cleavage plane and a division direction C2 is a direction perpendicular to the cleavage plane. In the GaN substrate 1 in FIG. 2, an orientation flat (OF) surface 10 is provided in a direction along the cleavage plane. The OF surface 10 shows the crystalline orientation of the GaN crystal in the GaN substrate 1. In general, when the division direction C1 is along the cleavage plane, division of the GaN substrate 1 in the direction C1 is performed by cleaving. The GaN substrate 1 is also divided in the direction C2, which is a direction perpendicular to the cleavage plane, by forming scribing lines and breaking the GaN substrate 1 therealong.

As in the first embodiment, when the OF surfaces 10 are provided in directions along cleavage planes, GaN substrates can be selected by measuring the dislocation density of the OF surfaces 10. However, there may be a case where the OF surfaces are provided in directions different from cleavage planes. In this case, it is preferred that surfaces along the cleavage planes be formed and the measurement be subsequently performed.

Next, a method for measuring the dislocation density in the OF surface 10 will be described.

A method for measuring the dislocation density in the OF surface 10 is a cathodoluminescence (CL) method, a transmission electron microscope (TEM) method, a light-scattering tomography method, a method (etch pits density: EPD) in which pits are formed by etching with a solvent and the pits are counted, or the like.

Any of the above-described methods can be used as a method for measuring the dislocation density in the OF surface 10 according to the first embodiment. However, use of the CL method or the light-scattering tomography method is preferred. This is because, while the TEM method and the EPD method are destructive inspections, the CL method and the light-scattering tomography method are nondestructive inspections and hence loss of GaN substrates caused by the measurement of dislocation density can be reduced. Specifically, the CL method is conducted by placing the OF surface 10 so as to be perpendicular to an electron gun and determining the number of dark spots. When the measurement is conducted by the CL method, the OF surface 10 to be observed is preferably formed by cleaving so that dark spots can be clearly observed. The light-scattering tomography method is conducted by making laser light incident on the OF surface 10 and determining the number and the length of dark lines through a surface on which an epitaxial layer is to be formed (that is, the principal surface of the GaN substrate 1) with an optical microscope. When the measurement is conducted by the light-scattering tomography method, the OF surface 10 is preferably a mirror surface formed by cleaving or the like so that laser light readily enters the OF surface 10.

When the dislocation density is measured by such a method, the GaN substrates 1 in which the dislocation density of the OF surfaces 10 of the GaN substrates 1 is 3.0×10⁶/cm² or less are preferably used for producing the semiconductor devices 110.

The inventors have found that generation of chipping, burrs, and cracks upon division of a GaN substrate into chip-shaped parts after formation of an epitaxial layer, electrodes, and the like on the GaN substrate is closely related to the defect density of the GaN substrate, in particular, the defect density in the lateral direction. To reduce the defect density of GaN substrates, in particular, the threading dislocation density of GaN substrates, the following methods have been employed.

The density of dislocations extending to a crystalline surface perpendicular to the growth direction of a crystal has been reduced by an epitaxial lateral overgrowth (ELO) method using a SiO₂ mask or a PENDEO method in which a substrate is processed so as to have projections and recesses and the growth is subsequently conducted so as to fill the recesses to thereby bend dislocations in the lateral direction. The dislocations of crystals grown by such a method are bent in the lateral direction. Observation of a section of such a crystal parallel to the growth direction of the crystal has revealed that the density of dislocations extending through the section is high.

Accordingly, it has been found that the presence of dislocations extending through a section parallel to the growth direction of a crystal causes lattice strain and division along the section (for example, a cleavage plane) into chip-shaped parts causes disarrangement of the division section and generates chipping or the like. Such generation of chipping or the like causes degradation of the yield of semiconductor devices.

Thus, as in the first embodiment, by measuring the dislocation density of sections of the GaN substrates 1, the sections intersecting with the principal surfaces of the GaN substrates 1, and producing the semiconductor devices 110 only with GaN substrates 1 in which the dislocation density is a predetermined value (3.0×10⁶/cm²) or less, generation of defectives caused by chipping or the like upon division of the GaN substrates 1 along the sections into chip-shaped parts can be reduced. Therefore, the yield of the semiconductor devices 110 can be enhanced.

In the first embodiment, when the GaN substrates 1 have a threading dislocation density of 4.2×10⁶/cm² or less, the yield of the semiconductor devices 110 can be further enhanced. A method for measuring the threading dislocation density of the GaN substrates 1 may be a CL method, a TEM method, a method (EPD) in which pits are formed by etching with a solvent and the pits are counted, or the like. However, use of the CL method, which is a nondestructive inspection, is preferred.

In the following second to fifth embodiments, semiconductor devices produced with the GaN substrates 1 having been selected by measuring the dislocation density of the OF surfaces 10 as in the first embodiment will be described in detail. Since the GaN substrate 1 is divided into a plurality of chip-shaped parts in the production process of the semiconductor devices, each semiconductor device includes the base 1A, which is a part of the GaN substrate 1.

### Second Embodiment

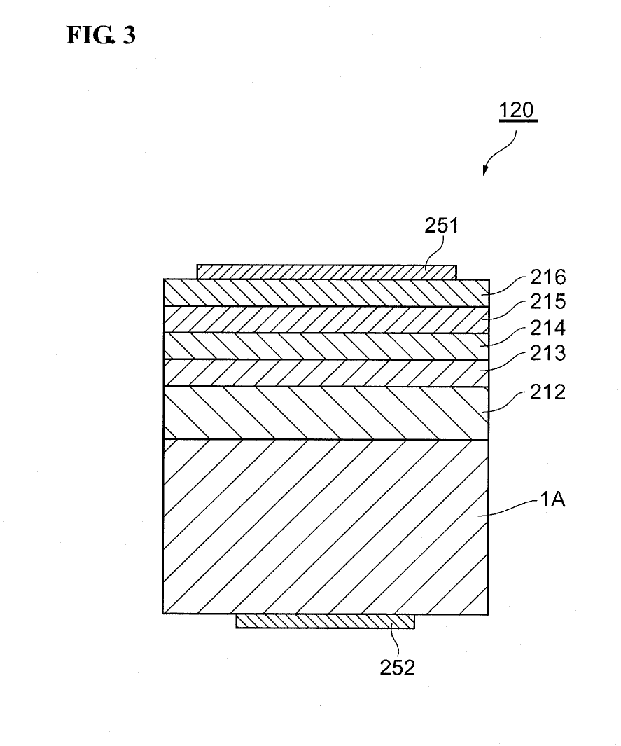

FIG. 3 is a sectional view of a semiconductor device 120 according to a second embodiment of the present invention. As illustrated in FIG. 3, the semiconductor device 120 according to the second embodiment includes a semiconductor layer in which an n-type GaN layer 212, an n-type AlGaN layer 213, a light emitting layer 214, a p-type AlGaN layer 215, and a p-type GaN layer 216 are sequentially formed on the principal surface of a base 1A; a p-side electrode 251 formed on the p-type GaN layer 216; and an n-side electrode 252 formed on the back surface of the base 1A. This semiconductor device 110 functions as a light emitting diode (LED). The light emitting layer 214 may have a multi-quantum well (MQW) structure in which, for example, GaN layers and In_{0.2}Ga_{0.8}N layers are alternately stacked.

The semiconductor devices 120 according to the second embodiment are produced by, for example, the following method. First, on the principal surface of the GaN substrate 1 having been selected by measuring the dislocation density of the OF surface 10, a layer having a thickness of 5 μm and serving as the n-type GaN layer 212, a layer serving as the n-type AlGaN layer 213, a layer (In_{0.2}Ga_{0.8}N layer) having a thickness of 3 nm and serving as the light emitting layer 214, a layer (Al_{0.2}Ga_{0.8}N layer) having a thickness of 60 nm and serving as the p-type AlGaN layer 215, and a layer having a thickness of 150 nm and serving as the p-type GaN layer 216 are sequentially formed by a MOCVD method. A part having a thickness of 100 nm and serving as the p-side electrode 251 is subsequently formed on the layer serving as the p-type GaN layer 216. The surface of the layer serving as the p-type GaN layer 205 is affixed to a holder for polishing, and the GaN substrate 1 is subsequently polished with slurry containing SiC abrasive grains having an average grain size of 30 μm so as to facilitate division into chip-shaped parts. An electrode serving as the n-side electrode 252 is formed on the back surface of the base 1A and the GaN substrate 1 is divided into chip-shaped parts. Thus, LEDs that are the semiconductor devices 120 are provided.

As in the second embodiment, by measuring the dislocation density of sections of the GaN substrates 1, the sections intersecting with the principal surfaces of the GaN substrates 1, and producing the semiconductor devices 120 (LEDs) with GaN substrates in which the dislocation density is a predetermined value or less, generation of defectives caused by chipping or the like upon division of the GaN substrates along the sections into chip-shaped parts can be reduced. Therefore, the yield of the semiconductor devices 120 (LEDs) can be enhanced.

### Third Embodiment

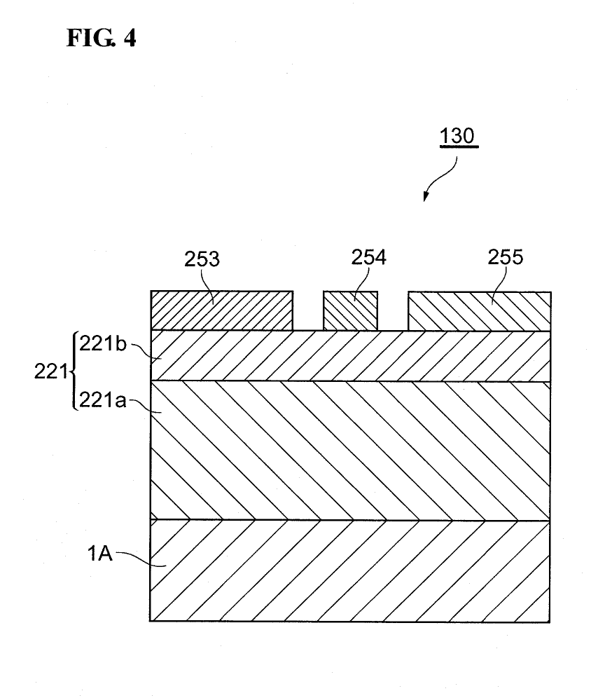

FIG. 4 is a sectional view of a semiconductor device 130 according to a third embodiment of the present invention. As illustrated in FIG. 4, the semiconductor device 130 according to the third embodiment includes a base 1A; a group III nitride semiconductor layer 221 in which an i-type GaN layer 221a and an i-type AlGaN layer 221b are sequentially stacked on the principal surface of the base 1A; and a source electrode 253, a gate electrode 254, and a drain electrode 255 that are formed on the i-type AlGaN layer 221b. The semiconductor device 130 functions as a highelectron mobility transistor (HEMT).

The semiconductor devices 130 according to the third embodiment are produced by, for example, the following method. On the principal surface of the GaN substrate 1 having been selected by measuring the dislocation density of the OF surface 10, a layer having a thickness of 3 μm and serving as the i-type GaN layer 221a and a layer (i-type Al_{0.15}Ga_{0.82}N layer) having a thickness of 30 nm and serving as the i-type AlGaN layer 221b are grown by a MOCVD method. The source electrode 253 and the drain electrode 255 constituted by a composite layer of Ti layer (thickness: 50 nm)/Al layer (thickness: 100 nm)/Ti layer (thickness: 20 nm)/Au layer (thickness: 200 nm) are subsequently formed by a photolithographic process and a liftoff process on the layer serving as the i-type AlGaN layer 221b. Then, the gate electrode 254 constituted by an Au layer having a thickness of 300 nm is further formed. At this time, the gate length is 2 μm and the gate width is 150 μm. The surface of the p-type GaN layer is then affixed to a holder for polishing, and the GaN substrate is subsequently polished with slurry containing SiC abrasive grains having an average grain size of 30 μm so as to facilitate division into chip-shaped parts. The GaN substrate is subsequently divided into chip-shaped parts to thereby provide HEMTs that are the semiconductor devices 130.

As in the third embodiment, by measuring the dislocation density of sections of the GaN substrates 1, the sections intersecting with the principal surfaces of the GaN substrates 1, and producing the semiconductor devices 130 (HEMTs) with GaN substrates in which the dislocation density is a predetermined value or less, generation of defectives caused by chipping or the like upon division of the GaN substrates along the sections into chip-shaped parts can be reduced. Therefore, the yield of the semiconductor devices 130 (HEMTs) can be enhanced.

### Fourth Embodiment

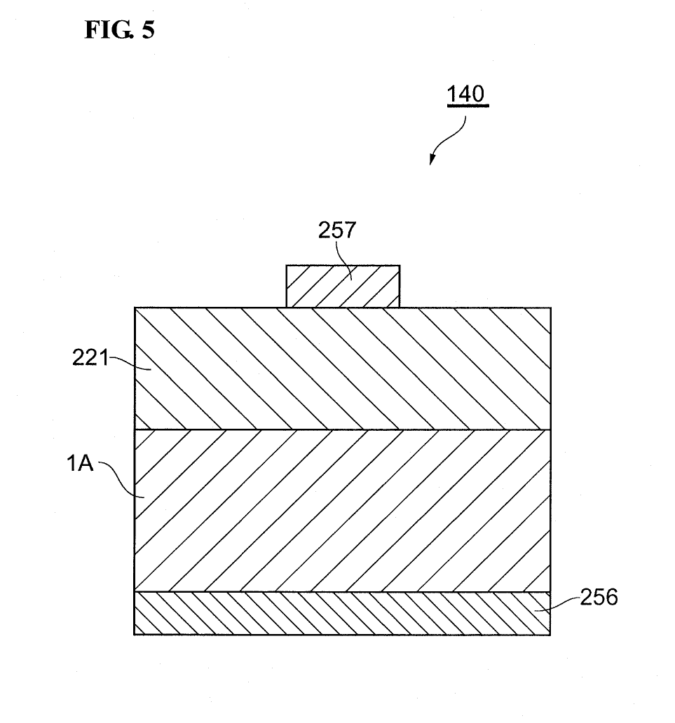

FIG. 5 is a sectional view of a semiconductor device 140 according to a fourth embodiment of the present invention. As illustrated in FIG. 5, the semiconductor device 140 according to the fourth embodiment includes, as one or more group III nitride semiconductor layers, an n⁻-type GaN layer 221 on the principal surface of a base 1A; and an ohmic electrode 256 on the back surface of the base 1A. The semiconductor device 140 further includes a Schottky electrode 257 on the principal surface of the n⁻-type GaN layer 221. The semiconductor device 140 functions as a Schottky diode.

The semiconductor devices 140 according to the fourth embodiment are produced by, for example, the following method. On the GaN substrate 1 having been selected by measuring the dislocation density of the OF surface 10, a layer (electron concentration: 1×10¹⁶ cm⁻³) serving as the n⁻-type GaN layer 221 is grown by a MOCVD method. The ohmic electrode 256 constituted by a composite layer of Ti layer (thickness: 50 nm)/Al layer (thickness: 100 nm)/Ti layer (thickness: 20 nm)/Au layer (thickness: 200 nm) is subsequently formed on the back surface of the GaN substrate 1. The Schottky electrode 257 constituted by an Au layer and having a diameter of 200 μm and a thickness of 300 nm is further formed by a photolithographic process and a liftoff process on the layer serving as the n⁻-type GaN layer 221. The surface of the p-type GaN layer is then affixed to a holder for polishing, and the GaN substrate is subsequently polished with slurry containing SiC abrasive grains having an average grain size of 30 μm so as to facilitate division into chip-shaped parts. The GaN substrate is subsequently divided into chip-shaped parts to thereby provide Schottky diodes that are the semiconductor devices 140.

As in the fourth embodiment, by measuring the dislocation density of sections of the GaN substrates 1, the sections intersecting with the principal surfaces of the GaN substrates 1, and producing the semiconductor devices 140 (Schottky diodes) with GaN substrates in which the dislocation density is a predetermined value or less, generation of defectives caused by chipping or the like upon division of the GaN substrates along the sections into chip-shaped parts can be reduced. Therefore, the yield of the semiconductor devices 140 (Schottky diodes) can be enhanced.

### Fifth Embodiment

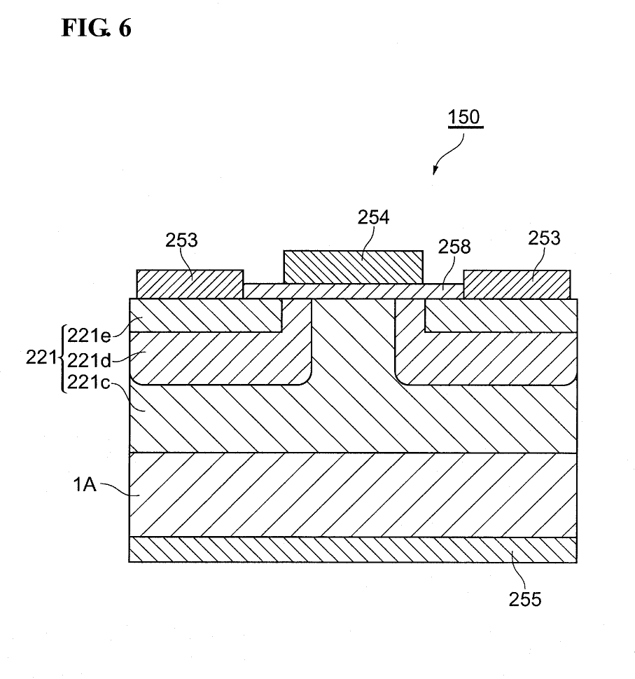

FIG. 6 is a sectional view of a semiconductor device 150 according to a fifth embodiment of the present invention. As illustrated in FIG. 6, the semiconductor device 150 according to the fifth embodiment includes a base 1A and a group III nitride semiconductor layer 221 including an n⁻-type GaN layer 221c formed on the principal surface of the base 1A and p-type GaN layers 221d and n⁺-type GaN layers 221e that are formed so as to be buried in two (left and right) portions on the n⁻-type GaN layer 221c. The semiconductor device 150 further includes a drain electrode 255 formed on the back surface of the base 1A, a gate electrode 254 formed on the n⁻-type GaN layer 221c with an insulation film 258 therebetween, and source electrodes 253 formed on the n⁺-type GaN layers 221e in the two portions. The semiconductor device 150 functions as a metalinsulator semiconductor (MIS) type transistor.

The semiconductor devices 150 according to the fifth embodiment are produced by, for example, the following method. On the GaN substrate 1 having been selected by measuring the dislocation density of the OF surface 10, a layer (electron concentration: 1×10¹⁶ cm⁻³) having a thickness of 5 μm and serving as the n⁻-type GaN layer 221c is formed by a MOCVD method. The p-type GaN layers 221d and the n⁺-type GaN layers 221e are then sequentially formed by a selective ion implantation method in a part of regions of the principal surface of the layer serving as the n⁻-type GaN layer. The principal surface of the portion serving as the n⁻-type GaN layer 221c is then protected with a SiO₂ film having a thickness of 300 nm and subsequently annealing is performed to thereby activate the implanted ions. A SiO₂ film is formed as an insulation film for MIS by a plasma enhanced chemical vapor deposition (P-CVD) method. Portions of the insulation film for MIS are subsequently etched by a photolithographic process and a selective etching method using buffered hydrofluoric acid and a liftoff process is performed to thereby form the source electrodes 253 constituted by a composite layer of Ti layer (thickness: 50 nm)/Al layer (thickness: 100 nm)/Ti layer (thickness: 20 nm)/Au layer (thickness: 200 nm) on the layer serving as the n⁺-type GaN layers 221e. A part serving as the gate electrode 254 constituted by an Al layer having a thickness of 300 nm is subsequently formed on the insulation film 258 for MIS by a photolithographic process and a liftoff process. To facilitate division into chip-shaped parts, the surface of the p-type GaN layer is then affixed to a holder for polishing. The GaN substrate is subsequently polished with slurry containing SiC abrasive grains having an average grain size of 30 μm and divided into chip-shaped parts. Finally, the drain electrode 255 constituted by a composite layer of Ti layer (thickness: 50 nm)/Al layer (thickness: 100 nm)/Ti layer (thickness: 20 nm)/Au layer (thickness: 200 nm) is formed on the entire back surface of the GaN substrate 1 to thereby provide MIS-type transistors that are the semiconductor devices 150.

As in the fifth embodiment, by measuring the dislocation density of sections of the GaN substrates 1, the sections intersecting with the principal surfaces of the GaN substrates 1, and producing the semiconductor devices 150 (MIS-type transistors) with GaN substrates in which the dislocation density is a predetermined value or less, generation of defectives caused by chipping or the like upon division of the GaN substrates along the sections into chip-shaped parts can be reduced. Therefore, the yield of the semiconductor devices 150 (MIS-type transistors) can be enhanced.

### EXAMPLES

Hereinafter, the present invention will be described in further detail with examples of semiconductor devices produced in accordance with production methods of embodiments. However, the present invention is not restricted to the following examples.

### 1. Example 1

A GaN substrate that had a principal surface of a (0001) plane and an OF surface cleaved at a (1-100) plane and had a thickness of 450 μm was prepared as a GaN substrate used for EXAMPLE 1. A threading dislocation density (principal-surface threading dislocation density) in the (0001) plane of the GaN substrate was measured with a CL device mounted to a scanning electron microscope (SEM) and it was 4.2×10⁶/cm². A dislocation density (lateral-direction dislocation density) in the OF surface was measured by a CL method and it was 3.0×10⁶/cm². Such a dislocation density was calculated by counting and averaging the number of dark spots in randomly selected five regions having a size of 100 μm×100 μm.

LDs that were the semiconductor devices 110 according to the first embodiment of the present invention and served as EXAMPLE 1 were produced with the GaN substrate. The detailed production method is as follows.

The following layers were sequentially epitaxially grown as a group III nitride semiconductor layer on the principal surface of the GaN substrate by a MOCVD method:

an n-type GaN buffer layer that was doped with Si and had a thickness of 0.05 μm;

an n-type Al_{0.08}Ga_{0.92}N cladding layer that was doped with Si and had a thickness of 1.0 μm;

an active layer having a multi-quantum well structure in which an n-type GaN optical waveguide layer that was doped with Si and had a thickness of 0.1 μm, an undoped In_{0.15}Ga_{0.85}N layer having a thickness of 3 nm, and an undoped In_{0.03}Ga_{0.97}N layer having a thickness of 6 nm were repeatedly stacked five times;

an undoped Al_{0.2}Ga_{0.8}N antidegradation layer having a thickness of 0.01 μm;
a p-type Al_{0.2}Ga_{0.8}N cap layer that was doped with magnesium (Mg) and had a thickness of 10 nm;

a p-type GaN optical waveguide layer that was doped with Mg and had a thickness of 0.1 μm;

a p-type Al_{0.08}Ga_{0.92}N cladding layer that was doped with Mg and had a thickness of 0.3 μm; and

a p-type GaN contact layer that was doped with Mg. The GaN substrate was subsequently removed from the MOCVD apparatus. A SiO₂ film having a thickness of 0.1 μm was subsequently formed by a CVD method over the entire surface of the p-type GaN contact layer. A pattern corresponding to the shape of a ridge portion was then formed in the SiO₂ film by lithography.

The p-type AlGaN cladding layer was subsequently etched by a RIE method to a predetermined depth in the thickness direction through the SiO₂ film serving as a mask to thereby form a ridge extending in the <1-100> direction. This ridge had a width of 2 μm. An etching gas used for the RIE was a chlorine-based gas.

The SiO₂ film having been used as the etching mask was subsequently removed by etching. A SiO₂ insulation film having a thickness of 0.3 μm was then formed by a CVD method over the entire surface of the substrate. A resist pattern covering the principal surface of the insulation film except for a region in which a p-side electrode was to be formed was subsequently formed by lithography. The insulation film was etched through the resist pattern serving as a mask to thereby form an opening.

While the resist pattern was left, the p-side electrode was subsequently formed over the entire surface of the substrate by a vacuum deposition method. The resist pattern was then removed together with the p-side electrode that was formed thereon. Thus, the p-side electrode was formed only on the p-type GaN contact layer. To facilitate division into chip-shaped parts, the surface of the p-type GaN layer was affixed to a holder for polishing. The GaN substrate was subsequently polished with slurry containing SiC abrasive grains having an average grain size of 2.5 μm until the thickness of the GaN substrate was decreased from 450 μm to 130 μm.

An n-side electrode was then formed on the back surface of the GaN substrate. The GaN substrate on which the laser structure had been formed as described above was subsequently scribed along outlines of device regions and divided into bar-shaped parts by cleaving. Scribing lines were subsequently formed in the bar-shaped parts in the direction perpendicular to the cleaving direction and the bar-shaped parts were subjected to breaking to thereby be divided into chips. Thus, semiconductor devices (LDs) in EXAMPLE 1 were provided.

The semiconductor devices provided by the above-described method were evaluated by the following methods. First, as for chip yield, the principal surfaces of the chips were observed with a microscope to confirm whether a chipping, cracking, or the like exists or not.

The cleaved end faces were further measured with an atomic force microscope (AFM) and evaluated as having passed or failed. As a result, the pass rate was found to be 79%.

As for device yield, the LDs were subsequently subjected to a life test. As for the test conditions, the atmosphere temperature was 70° C. and the optical output was 30 mW. LDs taking 3000 hours or more for which the current increased by 1.2 times upon constant optical output driving were evaluated as having passed. As a result, the pass rate was found to be 64%. The product of the above-described chip yield and the device yield was calculated as the total yield. The total yield of the semiconductor devices of EXAMPLE 1 was 50.6%.

### 2. Examples 2 to 7 and Examples 8 to 10

EXAMPLES 2 to 7 and EXAMPLES 8 to 10 were the same as EXAMPLE 1 except that GaN substrates were different from that of EXAMPLE 1. Specifically, nine GaN substrates that had a principal surface of a (0001) plane and an OF surface cleaved at a (1-100) plane and had a thickness of 450 were prepared. A threading dislocation density in the (0001) planes (principal surfaces) of the GaN substrates and a dislocation density (lateral-direction dislocation density) in the OF surfaces of the GaN substrates were measured by a CL method. From the result, substrates having a threading dislocation density of 4.2×10⁶/cm² or less and a lateral-direction dislocation density of 3.0×10⁶/cm² or less were used for EXAMPLES 2 to 7 and substrates having a lateral-direction dislocation density of more than 3.0×10⁶/cm² were used for EXAMPLES 8 to 10. Semiconductor devices (LDs) were produced with these GaN substrates by the same method as in EXAMPLE 1.

The chip yield, the device yield, and the total yield of the semiconductor devices provided by the above-described method were calculated by the same method as in EXAMPLE 1.

The results of EXAMPLES 1 to 10 are shown in Table I. Compared with EXAMPLES 8 to 10, EXAMPLES 1 to 7 had high chip yields and hence had high total yields.

TABLE I

| | Example 1 | Example 2 | Example 3 | Example 4 | Example 5 | Example 6 | Example 7 | Example 8 | Example 9 | Example 10 |
|---|---|---|---|---|---|---|---|---|---|---|
| Principal-surface | (0001) | (0001) | (0001) | (0001) | (0001) | (0001) | (0001) | (0001) | (0001) | (0001) |
| orientation | | | | | | | | | | |
| Principal-surface | 4.2 × 10⁶ | 3.9 × 10⁶ | 4.0 × 10⁶ | 1.5 × 10⁶ | 3.0 × 10⁵ | 1.5 × 10⁶ | 3.0 × 10⁵ | 3.1 × 10⁵ | 6.3 × 10⁶ | 6.3 × 10⁶ |
| threading dislocation | | | | | | | | | | |
| density (/cm²) | | | | | | | | | | |
| Lateral-direction | 3.0 × 10⁶ | 1.1 × 10⁶ | 3.0 × 10⁵ | 2.9 × 10⁶ | 3.1 × 10⁵ | 1.0 × 10⁶ | 2.6 × 10⁵ | 6.3 × 10⁶ | 2.9 × 10⁶ | 6.8 × 10⁶ |
| dislocation density | | | | | | | | | | |
| (/cm²) | | | | | | | | | | |
| Device type | LD | | | | | | | | | |
| Division method: C1 | Cleaving | | | | | | | | | |
| Division method: C2 | Scribing and breaking | | | | | | | | | |
| Chip yield (%) | 79 | 85 | 94 | 78 | 92 | 91 | 98 | 53 | 80 | 45 |
| Device yield (%) | 64 | 65 | 63 | 73 | 81 | 73 | 82 | 81 | 46 | 48 |
| Total yield (%) | 50.6 | 55.3 | 59.2 | 56.9 | 74.5 | 66.4 | 80.4 | 42.9 | 36.8 | 21.6 |

### 3. Examples 11 and 12

EXAMPLES 11 and 12 were the same as EXAMPLE 1 except that GaN substrates were different from that of EXAMPLE 1 in terms of the principal-surface orientation and the dislocation densities. Specifically, two GaN substrates that had a principal surface being off by 35° in the <11-20> direction with respect to a (0001) plane and an OF surface cleaved at a (1-100) plane and had a thickness of 450 μm were prepared. A threading dislocation density in the (0001) planes of the GaN substrates and a dislocation density (lateral-direction dislocation density) in the OF surfaces of the GaN substrates were measured by a CL method. From the result, the substrate having a threading dislocation density of more than 4.2×10⁶/cm² and a lateral-direction dislocation density of more than 3.0×10⁶/cm² was used for EXAMPLE 11 and the substrate having a threading dislocation density of 4.2×10⁶/cm² or less and a lateral-direction dislocation density of 3.0×10⁶/cm² or less was used for EXAMPLE 12. Semiconductor devices (LDs) were produced with these GaN substrates by the same method as in EXAMPLE 1.

The chip yield, the device yield, and the total yield of the semiconductor devices provided by the above-described method were calculated by the same method as in EXAMPLE 1.

The results of EXAMPLES 11 and 12 are shown in Table II. EXAMPLE 8 had a high chip yield and hence had a high total yield. Thus, it has been confirmed that similar results can also be obtained in the case where a different principal-surface orientation is employed.

TABLE II

| | Example 11 | Example 12 |
|---|---|---|
| Principal-surface | Off by 35° in the | Off by 35° in the |
| orientation | <11-20> direction | <11-20> direction |
| | with respect to (0001) | with respect to (0001) |
| Principal-surface | 7.0 × 10⁶ | 3.0 × 10⁵ |
| threading dislocation | | |
| density (/cm²) | | |
| Lateral-direction | 5.5 × 10⁶ | 2.6 × 10⁵ |
| dislocation density | | |
| (/cm²) | | |
| Device type | LD | |
| Division method: C1 | Cleaving | |
| Division method: C2 | Scribing and breaking | |
| Chip yield (%) | 42 | 91 |
| Device yield (%) | 45 | 78 |
| Total yield (%) | 18.9 | 71.0 |

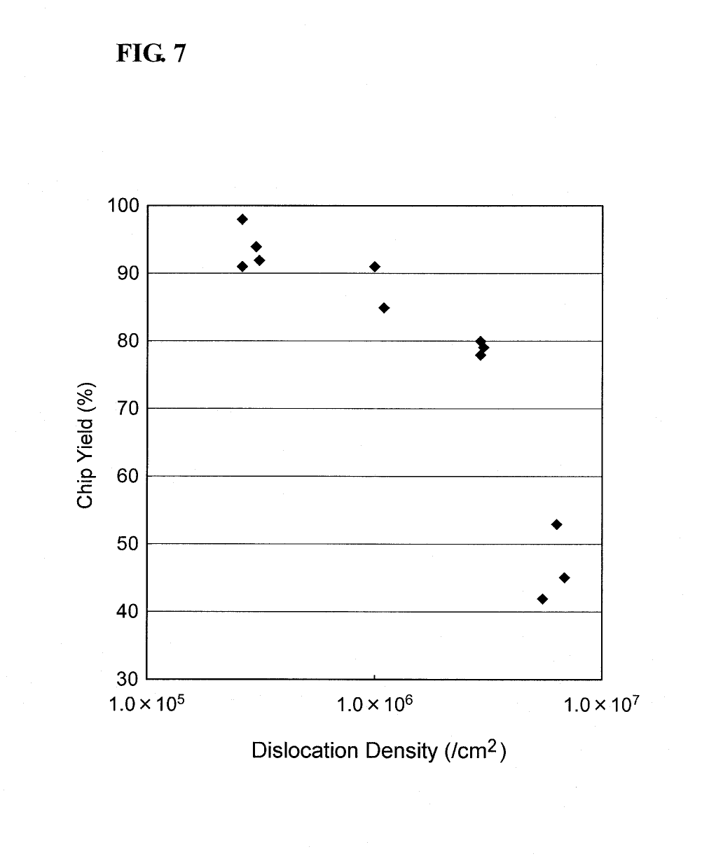

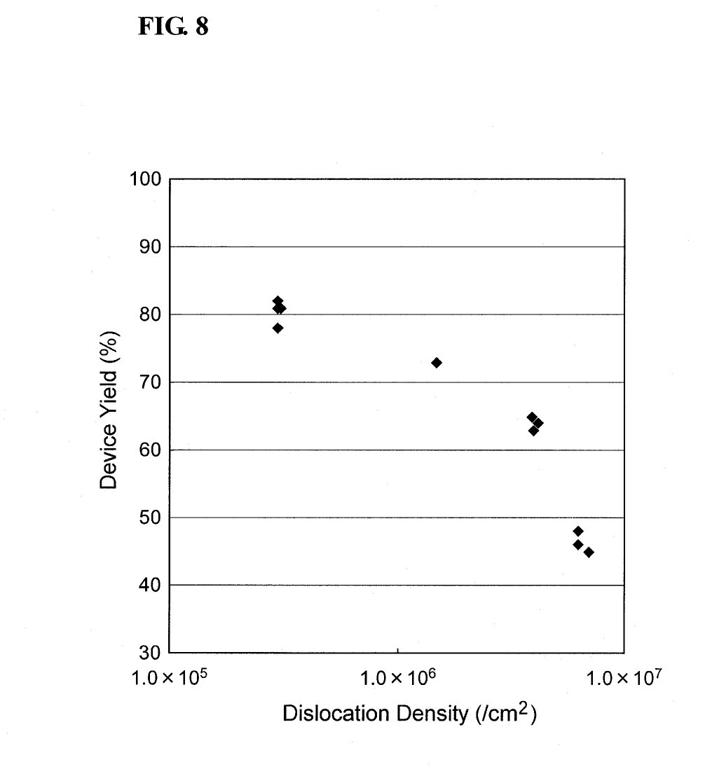

The results of EXAMPLES 1 to 12 are together illustrated in FIGS. 7 and 8. FIG. 7 is a graph illustrating the relationship between the lateral-direction dislocation density and the chip yield; and the abscissa axis indicates the lateral-direction dislocation density and the ordinate axis indicates the chip yield. FIG. 8 is a graph illustrating the relationship between the principal-surface threading dislocation density and the device yield; and the abscissa axis indicates the principal-surface threading dislocation density and the ordinate axis indicates the device yield.

Thus, it has been found that the dislocation densities of GaN substrates influence the chip yield and the device yield of semiconductor devices. It has also been found that the chip yield and the device yield of semiconductor devices depend on the lateral-direction dislocation density and the principal-surface threading dislocation density of GaN substrates but do not depend on growth methods, for example, vapor phase growth methods such as a MOCVD method and a HVPE method, and liquid phase growth methods such as a sodium flux method and an ammonothermal method. Accordingly, by defining a predetermined threshold value and producing semiconductor devices only using GaN substrates having a dislocation density of less than the threshold value, the yield can be enhanced. EXAMPLES above also show that the yield of semiconductor devices can be enhanced by defining the predetermined threshold value as “a threading dislocation density of 4.2×10⁶/cm² or less and a lateral-direction dislocation density of 3.0×10⁶/cm² or less” as with the reference (threshold value) used for separating EXAMPLES 1 to 7 and EXAMPLES 8 to 10.

The embodiments and EXAMPLES having been disclosed herein should be construed as illustrative in all the respects and not restrictive. The scope of the present invention is shown not by the above descriptions but by the claims and it is intended that the present invention encompasses concepts equivalent to the claims and all the modifications within the scope of the claims.

1. A method for producing semiconductor devices comprising:
a dislocation-density evaluation step of measuring a dislocation density of sections of GaN substrates, the sections intersecting with principal surfaces of the GaN substrates, and selecting a GaN substrate in which the dislocation density is a predetermined value or less; and
a division step of, after a functional device portion is epitaxially grown on the GaN substrate having been selected in the dislocation-density evaluation step, dividing the GaN substrate into chip-shaped parts.

2. The method for producing semiconductor devices according to claim 1, wherein the sections are along cleavage planes of the GaN substrates.

3. The method for producing semiconductor devices according to claim 1, wherein, in the dislocation-density evaluation step,
the dislocation density is measured by a cathodoluminescence method or a light-scattering tomography method.

4. The method for producing semiconductor devices according to claim 1, wherein the predetermined value is 3.0×10⁶/cm².

5. The method for producing semiconductor devices according to claim 1, wherein a principal surface of the GaN substrate has a threading dislocation density of 4.2×10⁶/cm² or less.
